(19) United States
(12) Patent Application Publication
(10) Pub. No.: US 2025/0393443 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: Oh June KWON, Yongin-si (KR); Soo Youn KIM, Yongin-si (KR); Soomin OH, Yongin-si (KR)

(21) Appl. No.: 19/094,884

(22) Filed: Mar. 29, 2025

(30) Foreign Application Priority Data
Jun. 25, 2024 (KR) 10-2024-0083175
Jul. 4, 2024 (KR) 10-2024-0088218

(51) Int. Cl. H10K 59/80; H10K 59/95

(52) U.S. Cl. CPC H10K 59/873; H10K 59/95

(57) ABSTRACT

A display device according to an embodiment includes a display panel, a flexible printed circuit board connected to the display panel, and a cover film printed or coated to a back surface of the display panel. The cover film defines a groove pattern therein, which accommodates at least a part of the flexible printed circuit board.

This application claims priority to Korean Patent Application No. 10-2024-0088218 filed on Jul. 4, 2024, and Korean Patent Application No. 10-2024-0083175 filed on Jun. 25, 2024, and all the benefits accruing therefrom under 35 U.S.C. § 119, the contents of which in their entirety are herein incorporated by reference.

### BACKGROUND

### (a) Technical Field

The present disclosure relates to a display device and an electronic device including the same.

### (b) Description of the Related Art

A display device includes pixels, and may display images on a display screen by controlling brightness of each pixel. The display device may include a display panel where the pixels are formed. The display device may include a flexible circuit board that is connected to the display panel and transmitting signals to the display panel. The display device may be used to display images in an electronic device.

### SUMMARY

Embodiments are to provide a display device that can reduce interference between components of an electronic device and increase usability of an internal space of the electronic device, and an electronic device including the same.

A display device according to an embodiment includes: a display panel, a flexible printed circuit board connected to the display panel, and a cover film printed or coated to a back surface of the display panel. The cover film defines a groove pattern therein, which accommodates at least a part of the flexible printed circuit board.

The at least a part of the groove pattern may have a planar shape, which corresponds to a planar shape of at least a part of the flexible printed circuit board.

The groove pattern may include a first groove having a first depth from a surface of the cover film and a second groove having a second depth from the surface of the cover film. The second depth may be greater than the first depth.

The flexible printed circuit board may include a body on which an electronic component is disposed, a tail extending from the body, and a connector disposed at an end of the tail. The tail may be disposed in the first groove and the connector may be disposed in the second groove.

The cover film may further have an additional groove pattern, which is spaced apart from the groove pattern.

The cover film may further have a protrusion pattern protruded from a major back surface of the cover film.

The cover film may further have a bump protruding from a major back surface of the cover film at an edge of the cover film.

The display panel may include a substrate, a transistor disposed on the substrate, a light-emitting device electrically connected to the transistor, and a protective film disposed on a back surface of the substrate. The cover film may directly contact the protective film.

The substrate may be a flexible substrate including a polymer layer.

The display panel may include a substrate, a transistor disposed on the substrate, and a light-emitting device electrically connected to the transistor. The cover film may directly contact the substrate.

The substrate may be a rigid substrate including glass.

The cover film may provide at least one of functions of shielding, buffering, light blocking, and heat dissipation.

The cover film may provide different functions depending on regions of the cover film.

An electronic device according to an embodiment includes a housing and a display device disposed in the housing. The display device includes a display panel and a cover film printed or coated on a back surface of the display panel. The cover film defines a groove pattern therein, which accommodates at least a part of a component.

The display device may further include a flexible printed circuit board connected to the display panel. At least a part of the groove pattern may have a planar shape corresponding to a planar shape of at least a part of the flexible printed circuit board.

The groove pattern may include a first groove having a first depth from a surface of the cover film and a second groove having a second depth from the surface of the cover film. The second depth may be greater than the first depth.

The flexible printed circuit board may include a body on which an electronic component is disposed, a tail extending from the body, and a connector disposed at an end of the tail. The tail may be disposed in the first groove and the connector is disposed in the second groove.

The cover film may further have a protrusion pattern protruded from a major back surface of the cover film.

The display panel may include a substrate, a transistor disposed on the substrate, a light-emitting device electrically connected to the transistor, and a protective film disposed on a back surface of the substrate. The cover film may directly contact the protective film.

The display panel may include a substrate, a transistor disposed on the substrate, and a light-emitting device electrically connected to the transistor. The cover film may directly contact the substrate.

According to the embodiments, a display device that can reduce interference between components of an electronic device and increase the usability of the internal space of the electronic device, and an electronic device including the same can be provided. In addition, according to the embodiments, there are beneficial effects that can be recognized throughout the specification.

### BRIEF DESCRIPTION OF THE DRAWINGS

FIG. 1 is a schematic front perspective view of an electronic device according to an embodiment.

FIG. 2 is a schematic front perspective view of a display device according to an embodiment.

FIG. 3 is a schematic top plan view of a connection relationship between components of the display device according to an embodiment.

FIG. 4 is a schematically perspective bottom view of the display device according to an embodiment.

FIG. 5 is a schematic cross-sectional view of the display device according to an embodiment, taken along line A-A′ of FIG. 4.

FIG. 6 is a schematic cross-sectional view of the display device according to an embodiment, taken along line A-A′ of FIG. 4.

FIG. 7 is a schematically perspective bottom view of a display device according to an embodiment.

FIG. 8 is a schematic side view of the display device according to an embodiment.

FIG. 9 is a schematic bottom perspective view of the display device according to an embodiment.

FIG. 10 schematically shows a bottom perspective view of a display device according to an embodiment.

FIG. 11 schematically shows a front perspective view of a display device according to an embodiment.

FIG. 12 is a schematic cross-sectional view of a display device according to an embodiment.

FIG. 13 is a schematic cross-sectional view of a display device according to an embodiment.

### DETAILED DESCRIPTION

The present disclosure will be described more fully hereinafter with reference to the accompanying drawings, in which are shown.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Unless explicitly described to the contrary, the word “comprise”, and variations such as “comprises” or “comprising”, will be understood to imply the inclusion of stated elements but not the exclusion of any other elements.

In addition, when “connected to” in the entire specification, this does not only mean that two or more constituent elements are directly connected, but also means that two or more constituent elements are indirectly connected, physically connected, and electrically connected through other constituent elements, or being referred to by different names depending on the position or function, while being integral.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In the drawing, the symbols “DR1”, “DR2”, and “DR3” are used to indicate directions, where “DR1” is a first direction, “DR2” is a second direction which is perpendicular to the first direction, and “DR3” is a third direction which is perpendicular to the first and second directions.

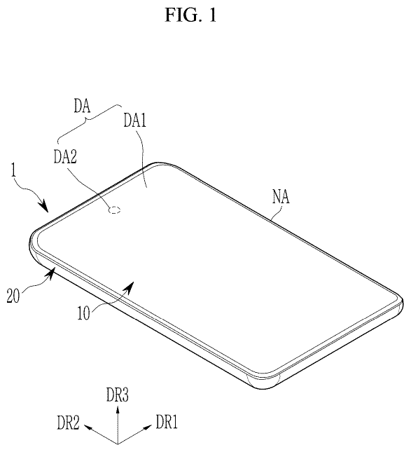

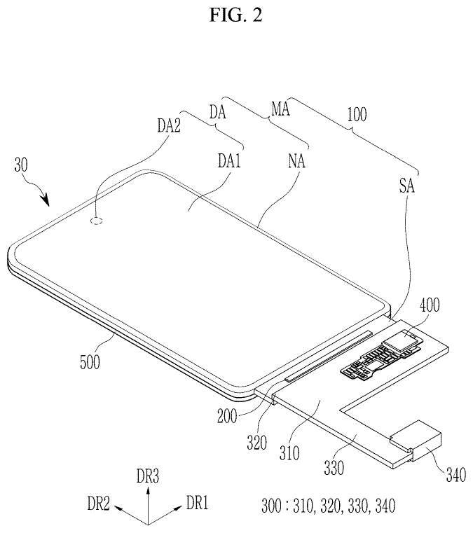

FIG. 1 is a schematic front perspective view of an electronic device according to an embodiment, and FIG. 2 is a schematic front perspective view of a display device according to an embodiment.

Referring to FIG. 1 and FIG. 2, an electronic device 1 may include a display screen that can display an image in a third direction DR3, which corresponds to the front on a plane defined by a first direction DR1 and a second direction DR2. The electronic device 1 may be a device including a smartphone, a mobile phone, a tablet, a multimedia player, a game machine, a monitor, a laptop a computer, and/or the like, which may include displaying images as its main function. The electronic device 1 may include a cover window 10, a housing 20, a display device 30, and/or the like.

The cover window 10 may include an insulating panel. For example, the cover window 10 may be formed of glass, plastic, or a combination thereof. The front of the cover window 10 may define the front of the electronic device 1. In the cover window 10, a region corresponding to the display screen can be optically transparent. The cover window 10 may be disposed over the display device 30 to protect the display device 30 from external impacts and the like and may transmit images displayed by the display device 30. In another embodiment, the cover window 10 may be considered as a component of the display device 30.

The housing 20 may be formed of a material with relatively high rigidity. For example, the housing 20 may include a plurality of frames and/or plat including glass, plastic, or metal, or formed of a combination of glass, plastic, or metal. The housing 20 may be combined with the cover window 10, and the combined housing 20 and cover window 10 may form the appearance of the electronic device 1 and provide an internal space of the electronic device 1. For example, the housing 20 may form the back and side surfaces of electronic device 1, and the cover window 10 may form the front surface of the electronic device 1. The display device 30 and the like may be disposed in the internal space defined by the cover window 10 and the housing 20 such that the display device 30 and the like can be protected from the external environment.

The display device 30 may display an image and may provide a display screen of the electronic device 1. The display device 30 may be an emissive display device such as an organic light emitting display device, an inorganic emissive display device, or a quantum dot emissive display device.

The electronic device 1 may have various shapes. As shown in FIG. 1, the electronic device 1 may be a quadrangle with rounded corners when viewed from the front. In addition, the electronic device 1 may have a rectangular shape, a square, other shapes such as a polygon, a circle, an oval, and/or the like.

The electronic device 1 and the display device 30 each may include a display area DA and a non-display area NA. The display area DA and the non-display area NA shown in FIG. 1 may correspond to display area DA and the non-display area NA shown in FIG. 2. The display area DA is a region where the image is displayed and may correspond to the display screen. The non-display area NA is a region where the image is not displayed. The display area DA may occupy most of the region centered on the front side of the electronic device 1, and the non-display area NA may surround the display area DA.

The display area DA may include a first display area DA1 and a second display area DA2. The second display area DA2 may be a region where components such as sensors and cameras are disposed on the back to add various functions to the electronic device 1. The second display area DA2 may correspond to a component region. The second display area DA2 may be surrounded by the first display area DA1. Not only the first display area DA1, but also the second display area DA2 may display images. The position and number of the second display areas DA2 may be changed in various ways. In more detail, the display device 30 may provide a display screen on the electronic device 1. The display device 30 may detect or capture the front of the electronic device 1. The display device 30 may have a similar flat shape to the electronic device 1.

The display device 30 may include a display panel 100, a display driver 200, a flexible printed circuit board 300, a touch driver 400, a cover film 500, and the like.

The display panel 100 may be attached to the cover window 10 by an adhesive layer. The display panel 100 may include a main area MA and a sub area SA.

The main area MA may include a display area DA where pixels displaying an image are arranged, and a non-display area NA surrounding the display area DA. The display area DA may include a first display area DA1 and a second display area DA2. Components such as sensors and cameras may be disposed on a rear side of the second display area DA2. The second display area DA2 may correspond to a component area.

The display area DA may emit light in the third direction DR3 from light emitting regions corresponding to the light-emitting devices. For example, the display panel 100 may include a pixel circuit portion including transistors, signal lines (e.g., gate lines, data lines, voltage lines) connected to the pixel circuit portion, and a light-emitting device connected to the pixel circuit portion. The display panel 100 may include a pixel definition layer providing openings defining a light emitting region of each light-emitting device. The light-emitting device may include an organic light-emitting diode including an organic light-emitting layer, a quantum dot light-emitting diode including a quantum dot light-emitting layer, an inorganic light-emitting diode including an inorganic semiconductor, or a micro light-emitting diode.

The non-display area NA may surround the display area DA. The non-display area NA may be defined as a peripheral area of the main area MA of the display panel 100. Circuits and/or signal lines for generating and/or transmitting various signals applied to the display area DA may be arranged in the non-display area NA. For example, a gate driver (not shown) that supplies gate signals to the gate lines and fan-out lines (not shown) that connect the signal lines of the display driver 200 and the display area DA may be disposed in the non-display area NA.

The sub area SA may be an area extending from one side of the main area MA. The sub area SA may include a flexible area capable of bending, folding, and rolling. For example, the sub area SA may be bent to overlap with the main area MA in a thickness direction (i.e., the third direction DR3). The display driver 200 may be disposed in the sub area SA, and a pad area may be disposed at an edge of the sub area SA. A flexible printed circuit board 300 may be connected to the pad area. In another embodiment, the sub area SA may be omitted, and the display driver 200 and the pad area may be arranged in the non-display area NA.

The display driver 200 may output signals and voltages for driving the display panel 100. The display driver 200 may supply data voltages to the data lines. The display driver 200 may supply a power voltage to power lines, and may supply gate control signals to a gate driver. The display driver 200 may be provided as an IC chip and mounted on the display panel 100. For example, the display driver 200 may be placed in the sub area SA and overlap with the main area MA in the thickness direction (i.e., the third direction DR3) by bending the sub area SA. In another embodiment, the display driver 200 may be mounted on the flexible printed circuit board 300.

The flexible printed circuit board 300 may include a body 310, a connection part 320, a tail 330, and a connector 340.

The body 310 may occupy the largest area in the flexible printed circuit board 300 and may be multi-layered. For example, the body 310 may include four or more conductive layers. Electronic components such as a touch driver 400, a capacitor, a resistor, and an inductor may be provided in the body 310.

The connection part 320 may be disposed along an edge of the body 310. The connection part 320 may be referred to as a compression part or a pad area. The connection part 320 may extend in the first direction DR1. The connection part 320 may be joined to the pad area of the display panel 100 using an electrical or physical junction means, such as an anisotropic conductive film. Pads disposed in the connection parts 320 of the flexible printed circuit board 300 may be electrically connected to pads disposed in the pad area of the display panel 100. The connection part 320 may include one or more conductive layers. The number of conductive layers included in the connection part 320 may be less than the number of conductive layers included in the body 310. For example, the connection part 320 may include one or two layers of conductive layers, and the body 310 may include four or more layers of conductive layers.

A tail 330 may extend from the body 310, and a connector 340 may be disposed at an end of the tail 330. The tail 330 may be approximately straight in plan or may be bent one or more times. The number of conductive layers included in the tail 330 may be less than the number of conductive layers included in the body 310. For example, the tail 330 may include one or two layers of conductive layers, and the body 310 may include four or more layers of conductive layers.

The connector 340 may be disposed at an edge of the tail 330. The connector 340 may include connection terminals, such as pins connected to a wiring of the tail 330. The connector 340 may be connected to an external device such as a graphic system, a power system, and the like to receive digital video data and receive power. A mobile industry processor interface (“MIPI”) may be used for high-speed transmission of digital video data. Signals and power applied through the connector 340 may be transmitted to a wiring arranged in the body 310 through a wiring arranged in the tail 330. The connector 340 may be thicker than other portions of the flexible printed circuit board 300.

The touch driver 400 may be provided as an IC chip and mounted on a flexible printed circuit board 300. The touch driver 400 may be electrically connected to a touch detector included in the electronic device 1. The touch detector may be provided in the display area DA of the display panel 100. The touch driver 400 may supply an input signal (touch driving signal) to sensing electrodes of the touch detector, and detect a change in electrostatic capacitance between the sensing electrodes based on an output signal (touch detection signal) from the sensing electrodes. For example, the touch driving signal may be a pulse signal with a predetermined frequency. The touch driver 400 may calculate touch presence and touch position based on the change in electrostatic capacitance between the sensing electrodes.

The cover film 500 may be disposed on the back of the display panel 100. The cover film 500 may be printed or coated on the back of the display panel 100. Therefore, the cover film 500 may be attached to the display panel 100 by itself without an attachment means such as an adhesive or adhesive layer, and may be in direct contact with the back surface of the display panel 100. The cover film 500 may protect the display panel 100 from the back environment of the display panel 100, for example, impact, electromagnetic waves, heat, noise, and the like.

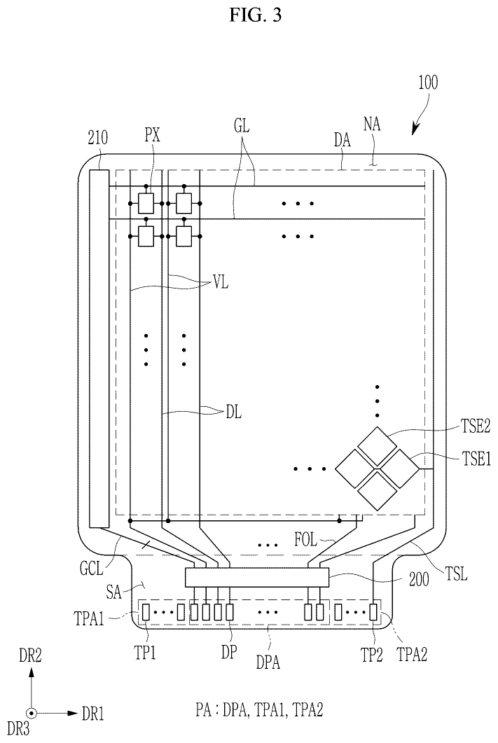

FIG. 3 is a schematic top plan view of a connection relationship between components of the display device according to an embodiment. As used herein, the plan view is a view in a thickness direction (i.e., third direction DR3) of the display device 30.

Referring to FIG. 3, the display panel 100 of the display device 30 may include a display area DA and a non-display area NA. The display area DA may be disposed at a center of the display panel 100. Pixels PX, gate lines GL, data lines DL, and power lines VL may be disposed in the display area DA. As the minimum unit that emits light, each pixel PX may include a pixel circuit portion including a transistor and a capacitor, and a light-emitting device that receives a driving current from the pixel circuit portion. The pixel PX may be connected with the gate line GL, the data line DL, and the [symbol] power line VL.

The gate lines GL may supply a gate signal applied from the gate driver 210 to the pixels PX. The gate lines GL may extend in the first direction DR1 and may be spaced apart from each other in the second direction DR2. The data lines DL may supply a data voltage applied from the display driver 200 to the pixels PX. The data lines DL may extend in the second direction DR2 and spaced apart from each other in the first direction DR1. The power lines VL may supply power voltages applied from the display driver 200 to the pixels PX. The power voltages may include a high-potential power voltage (or driving voltage), a low-potential power voltage (or common voltage), an initialization voltage, and the like, and these power voltages may be transmitted to the pixel PX. The power lines VL may extend in the second direction DR2 and spaced apart from each other in the first direction DR1.

Sense electrodes TSE1 and TSE2 that detect touch may be placed in the display area DA. The sense electrodes TSE1 and TSE2 may include first sense electrodes TSE1 arranged in the first direction DR1 and second sense electrodes TSE2 arranged in the second direction DR2.

The non-display area NA may surround the display area DA. A gate driver 210, fan-out lines FOL, gate control lines GCL, and touch signal lines TSL may be disposed in the non-display area NA. The gate driver 210 may generate gate signals based on the gate control signals GCL, and may supply the gate signals according to a predetermined order to the gate lines GL. The fan-out lines FOL may extend to the display area DA from the display driver 200. The fan-out lines FOL may transmit data voltages output from the display driver 200 to the data lines DL. The gate control lines GCL may extend to the gate driver 210 from the display driver 200. The gate control lines GCL may transmit the gate control signals output from the display driver 200 to the gate driver 210. The touch signal lines TSL may electrically connect the touch pads TP1 and TP2 and the sense electrodes TSE1 and TSE2.

The display panel 100 may include a sub area SA. The display driver 200 may be disposed in the sub area SA. The sub area SA may include a pad area PA.

The display driver 200 may output signals and voltages for driving the display panel 100. The display driver 200 may supply data voltages to the data lines DL through the fan-out lines FOL. The data voltages may be supplied to the pixels PX and may control illuminances of the pixels PX. The display driver 200 may supply gate control signals to the gate driver 210 through the gate control lines GCL.

The pad area PA may be disposed at an edge of the sub area SA. The pad area PA may include a display pad area DPA, a first touch pad area (voltage line VL) 1, and a second touch pad area TPA2. Display pads DP may be disposed in the display pad area DPA. The display pads DP may be connected to a graphic system through the flexible printed circuit board 300. The display pads DP may be connected with the flexible printed circuit board 300 and thus receive digital video data, and may supply the digital video data to the display driver 200. The first touch pad area TPA1 and the second touch pad area TPA2 may be disposed in one side and the other side of the display pad area DPA. The touch pads TP1 and TP2 may be disposed in the first touch pad area TPA1 and the second touch pad area TPA2, and the touch pads TP1 and TP2 are connected to the sense electrodes TSE1 and TSE2 disposed in the display area DA and the touch driver 400 disposed on the flexible printed circuit board 300 to detect touch. The pad area PA, the first touch pad area TPA1, and the second touch pad area TPA2 may be electrically connected to the flexible printed circuit board 300 by an anisotropic conductive film or self-assembly anisotropic conductive paste (“SAP”).

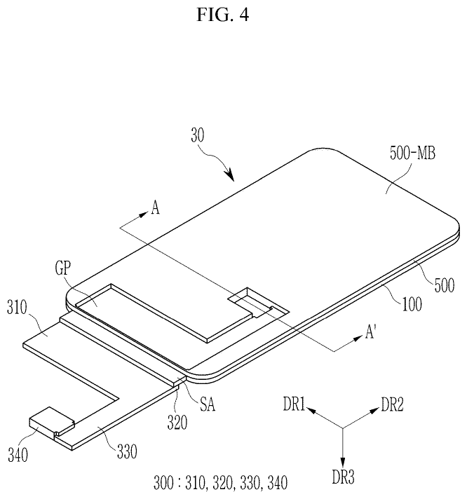

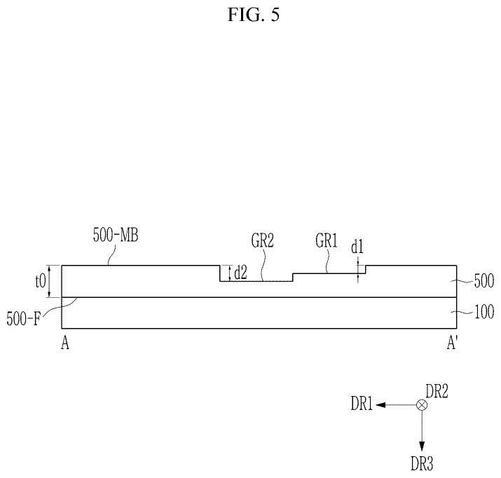

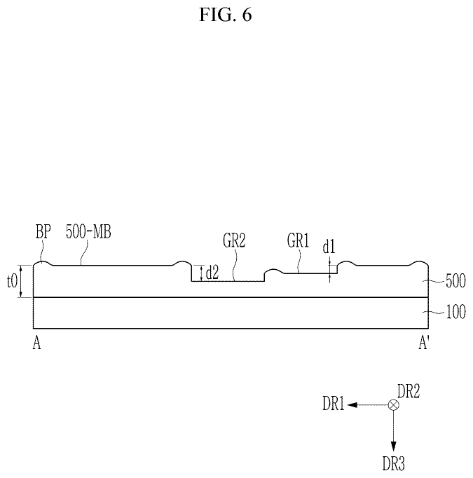

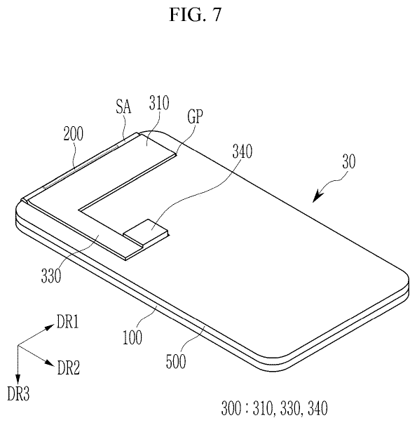

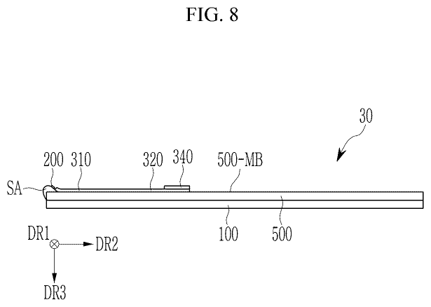

FIG. 4 is a schematically perspective bottom view of the display device according to an embodiment, FIG. 5 and FIG. 6 are schematic cross-sectional view of the display device according to an embodiment, taken along line A-A′ of FIG. 4, FIG. 7 is a schematically perspective bottom view of a display device according to an embodiment, and FIG. 8 is a schematic side view of the display device according to an embodiment.

FIG. 4 shows a state the display panel 100 or the flexible printed circuit board 300 before bending, and FIG. 7 shows a state the display panel 100 or the flexible printed circuit board 300 after bending.

Referring to FIG. 4, a cover film 500 may be disposed on the back surface of the display panel 100. The cover film 500 may be formed by printing or coating a functional material on the back surface of the display panel 100 using an inkjet printing method, and the like. The cover film 500 may protect the display panel 100 from the back environment. For this, the cover film 500 may include at least one of functional layers such as a shielding layer, a cushion layer, a light blocking layer, a heat dissipation layer, and the like.

The shielding layer may prevent electromagnetic interference (“EMI”) and the like from flowing from the back surface of the cover film 500 to the display panel 100. The shielding layer may include a conductive material. For example, the shielding layer may include silver flakes, silver nanowires (AgNW), carbon nanotubes (“CNT”), copper powder, aluminum powder, and/or the like.

The cushion layer may absorb impact and prevent damage to the display panel 100. For example, the cushion layer may prevent damage to the display panel 100 caused by external impact and alleviate impact and stress when the electronic device 1 is dropped. The cushion layer may be a porous layer formed of a material such as polyurethane, disperse polyurethane, epoxy resin, or polyethylene. The cushion layer may contain foam resin.

The light blocking layer may block light entering the display panel 100 from the back surface of the display panel 100 and may block the inside of the display device 30 from being viewed. The light blocking layer may include a polymer (e.g., black polyethylene terephthalate) containing a black dye or pigment.

The heat dissipation layer may dissipate heat generated from heat-generating elements such as processors and batteries.

The heat dissipation layer may contain a material with excellent thermal conductivity. The heat dissipation layer may contain carbon materials such as graphite, graphene, or carbon nanotubes.

The cover film 500 may further include a support layer to ensure strength. The support layer may be a plastic layer made of a polymer such as polyimide, polyethylene terephthalate, and/or the like.

Each functional layer may be formed separately, or one layer may be formed to perform a plurality of functions. For example, the cushion layer may be a black foam resin layer including a black dye or pigment, or may include a light blocking layer function. Even if each functional layer is formed separately, it may be formed integrally without layer distinction because it is formed using an inkjet printing method, and the like. Each functional layer may be formed over the entire region of the cover film 500 or may be formed in a partial region.

In another embodiment, the cover film 500 may further include a primer layer (e.g., silicon primer layer) as a layer in contact with the display panel 100 to increase the adhesion of the function layers to the display panel 100. The primer layer may be printed or coated on the back surface of the display panel 100.

Referring to FIG. 4, FIG. 5, FIG. 6, FIG. 7, and FIG. 8, the cover film 500 may define a groove pattern GP formed in the back surface thereof. The groove pattern GP may be concave with respect to a major back surface 500-MB of the cover film 500. Here, the major back surface 500-MB is a portion of the entire back surface of the cover film 500, which has the largest area of the entire back surface and a uniform thickness (i.e., t0). The groove pattern GP may be an engraved pattern. As the groove pattern GP is defined in the cover film 500, the cover film 500 may include portions with different thicknesses. The cover film 500 may have a thickness to between the major back surface 500-MB and a front surface 500-F thereof, and a portion where the groove pattern GP is defined may have a thickness thinner than the thickness t0. Such a groove pattern GP may be formed by varying the thickness of the functional material depending on regions during printing or coating of the functional material forming the cover film 500. For example, in a region where the groove pattern GP is to be defined on the back surface of display panel 100, a groove pattern GP having a relatively thin thickness may be formed by printing a functional material thinner than in other regions (e.g., the major back surface 500-MB).

The groove pattern GP may correspond to a planar shape of a component disposed on the back surface of the cover film 500. In an embodiment, at least a part of the groove pattern GP may correspond to the planar shape of the flexible printed circuit board 300. In an embodiment, the groove pattern GP may correspond to at least a part of the planar shape of the flexible printed circuit board 300. The sub area SA of the display panel 100 may be bent, and thus a part of the sub area SA may be disposed on a back surface of the main area MA and the back surface of the cover film 500. In addition, the flexible printed circuit board 300 including the connection part 320 connected to the pad area PA of the sub area SA may be disposed on the back surface of the main area MA and the back surface of the cover film 500 as the sub area SA is bent. The flexible printed circuit board 300 may be attached to the back surface of the cover film 500 and fixed in position by an adhesive member such as an adhesive or double-sided adhesive tape. The groove pattern GP may accommodate at least a part of the flexible printed circuit board 300, thereby reducing a portion of the flexible printed circuit board 300 that protrudes from the cover film 500. The groove pattern GP may also accommodate an adhesive member to hold the flexible printed circuit board 300 in position. The overall thickness of the display device 30 can be reduced as the flexible printed circuit board 300 protrudes less by the groove pattern GP. In addition, interference with other components provided on the back surface of the display device 30 within the electronic device 1 may be reduced, and space utilization within the electronic device 1 may be increased, allowing for more freedom in the layout design of other components.

An edge of the cover film 500 may be flat, as shown in FIG. 5, or slightly raised, as shown in FIG. 6. When the cover film 500 is printed or coated using an inkjet printing method, a bump BP shape may occur at the edge of the cover film 500 due to the characteristics and energy aspects (surface tension, etc.) of the liquid material being applied. The bump BP may have a shape protruding from the surface of the cover film 500. Due to the bump BP, the edge of the cover film 500 may be thicker than other portions (e.g., the major back surface 500-MB) of the cover film 500. Such a bump BP may exist in the display device 30 in which a plurality of display panels 100 are manufactured from a mother board, the plurality of display panels 100 are cut into cell units, and then the cover film 500 is formed on the back surface of each display panel 100. In a display device 30 cut into cell units after manufacturing a plurality of display panels 100 from a mother board and forming the cover film 500 on the back surface of the plurality of display panels 100, the bump BP may not exist. This is because when cutting into cell units, a portion where the bump BP is disposed may be cut off.

The groove pattern GP of the cover film 500 may include regions with different depths. For example, the groove pattern GP may include a first groove GR1 having a first depth d1 and a second groove GR2 having a second depth d2 from the surface of the cover film 500. In a region where the first groove GR1 is defined, the cover film 500 may have a thickness corresponding to t0 minus d1, and in a region where the second groove GR2 is defined, the cover film 500 may have a thickness corresponding to t0 minus d2. The first groove GR1 and the second groove GR2 may be connected to each other. The first groove GR1 may correspond to the tail 330 of the flexible printed circuit board 300. The second groove GR2 may correspond to the connector 340 of the flexible printed circuit board 300. The connector 340 may be thicker than other portions of the flexible printed circuit board 300, for example the tail 330. Therefore, by forming the second depth d2, which is the depth of the second groove GR2 corresponding to the connector 340, greater than the first depth d1, which is the depth of the first groove GR1 corresponding to the tail 330, the protruding of the connector 340 from the major back surface 500-MB of the cover film 500 can be reduced. In an embodiment, the depth of the region corresponding to the connection part 320 or the body 310 of the flexible printed circuit board 300 in the groove pattern GP may be approximately equal to or greater than the first depth d1. In another embodiment, the groove pattern GP may further include groove(s) with depth(s) different from the first depth d1 and the second depth d2.

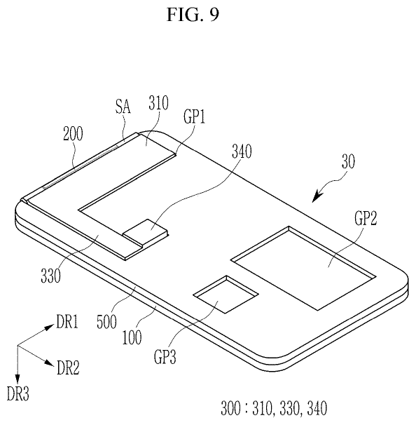

FIG. 9 is a schematic bottom perspective view of the display device according to an embodiment.

Referring to FIG. 9, the cover film 500 may further define groove patterns GP2 and GP3 in the back surface thereof in addition to the first groove pattern GP1 corresponding to the flexible printed circuit board 300. The groove patterns GP2 and GP3 may correspond to the shapes of the components of the electronic device 1. For example, one of the groove patterns GP2 and GP3 may have a shape corresponding to a bracket, and the other may have a shape corresponding to another flexible printed circuit board. The groove patterns GP2 and GP3 may accommodate some of the components and increase the internal space utilization of the electronic device 1. Although three groove patterns GP1, GP2, and GP3 are shown, the cover film 500 may include fewer or more groove patterns in another embodiment.

Depths of the groove patterns GP2 and GP3 may be the same as or different from the depth of the groove pattern GP1. The depth of the groove pattern GP2 may be the same as or different from the depth of the groove pattern GP3. Since the cover film 500 is formed by printing or coating, the thickness of the cover film 500 may be varied depending on the region, and depths of the groove patterns GP1, GP2, and GP3 may be adjusted.

In the cover film 500, the portions where groove patterns GP1, GP2, and GP3 are formed may have different functions. For example, when heat generated from components accommodated in the groove pattern GP2 may affect the display panel 100, a portion of the cover film 500 where the groove pattern GP2 is defined may include a heat dissipation layer. When electromagnetic waves generated from components accommodated in the groove pattern GP3 may affect the display panel 100, a portion of the cover film 500 where the groove pattern GP3 is defined may include a shielding layer. When the pressing of the flexible printed circuit board 300 accommodated in the groove pattern GP1 may affect the display panel 100, a portion of the cover film 500 where the groove pattern GP1 is defined may include a cushion layer. In the cover film 500, the respective portions where the groove patterns GP1, GP2, and GP3 are formed may include a layer having one or more functions, such as shielding, buffering, light blocking, and heat dissipation. Since the cover film 500 can be formed by an inkjet printing method, and the like, the function for the cover film 500 may be improved by printing or coating different materials.

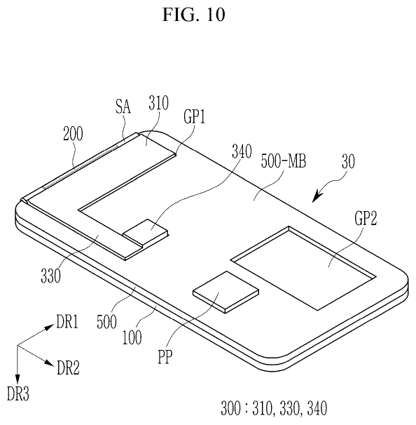

FIG. 10 schematically shows a bottom perspective view of a display device according to an embodiment.

Referring to FIG. 10, a cover film 500 may define a groove pattern GP2 in the back surface thereof and include a protrusion pattern PP in addition to a first groove pattern GP1 corresponding to a flexible printed circuit board 300. The groove pattern GP2 may be the same as described in the embodiment of FIG. 9. The protrusion pattern PP may protrude further than the major back surface 500-MB. In the cover film 500, a portion where the protrusion pattern PP is formed may be thicker than other portions of the cover film 500 (e.g., the major back surface 500-MB). Since the cover film 500 may be formed by printing or coating using an inkjet printing method, the thickness of the cover film 500 may be formed partially thicker than other portions. For example, when a portion where the protrusion pattern PP is formed requires higher impact characteristics than other portions, a cushion layer may be formed thicker than the thickness of the protrusion pattern PP to absorb the impact or disperse the stress, thereby protecting the display panel 100. Although two groove patterns GP1 and GP2 and one protrusion pattern PP are shown, the cover film 500 may define fewer or more groove patterns therein and include protrude patterns in another embodiment.

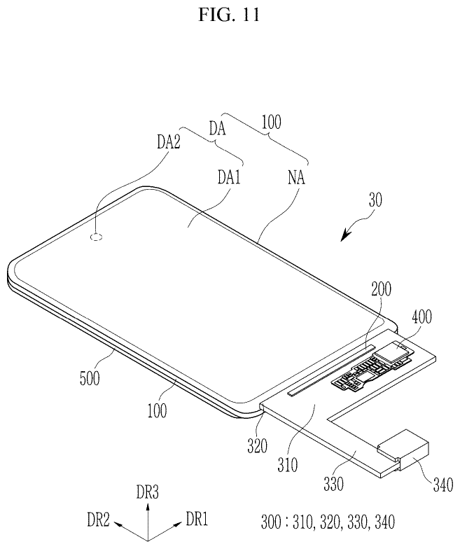

FIG. 11 schematically shows a front perspective view of a display device according to an embodiment.

Referring to FIG. 11, a display device 30 may include a display panel 100, a display driver 200, a flexible printed circuit board 300, a touch driver 400, a cover film 500, and the like. The differences between the display device 30 illustrated in FIG. 11 and the display device 30 illustrated in FIG. 2 will be mainly explained.

Unlike the display panel 100 shown in FIG. 2, the display panel 100 may include a display area DA and a non-display area NA at the periphery of the display area DA rather than including a sub area SA. The display driver 200 may be disposed in the flexible printed circuit board 300. The display driver 200 may be disposed in the non-display area NA of the display panel 100. The flexible printed circuit board 300 may be connected to a pad area disposed at an edge of the display panel 100. The touch driver 400 may be disposed on the flexible printed circuit board 300. The cover film 500 may be disposed on a back surface of the display panel 100 and may be printed or coated on the back surface of the display panel 100.

The flexible printed circuit board 300 may be bent at a portion between the body 310 and the connection part 320 (hereinafter, referred to as “bending portion”), and most of the flexible printed circuit board 300 (i.e., the body 310, the tail 330, and the connector 340) may be disposed on the back surface of the display panel 100 and the cover film 500. In the display device 30 shown in FIG. 2, the flexible printed circuit board 300 may be disposed on the back of the display panel 100 by bending the sub area SA of the display panel 100, but in the display device 30 shown in FIG. 11, the flexible printed circuit board 300 may be disposed on the back surface of the display panel 100 and the back surface of the cover film 500 by bending of the bending portion of the flexible printed circuit board 300. The flexible printed circuit board 300 may be attached to the back surface of the cover film 500 and fixed in position by an adhesive means. Even in such a structure, the cover film 500 may correspond to the planar shape of the flexible printed circuit board 300 and may include the aforementioned groove pattern GP that accommodates at least a part of the flexible printed circuit board 300. In addition, the cover film 500 may include at least one of the aforementioned groove patterns GP1, GP2, and GP3 and the protrusion pattern PP.

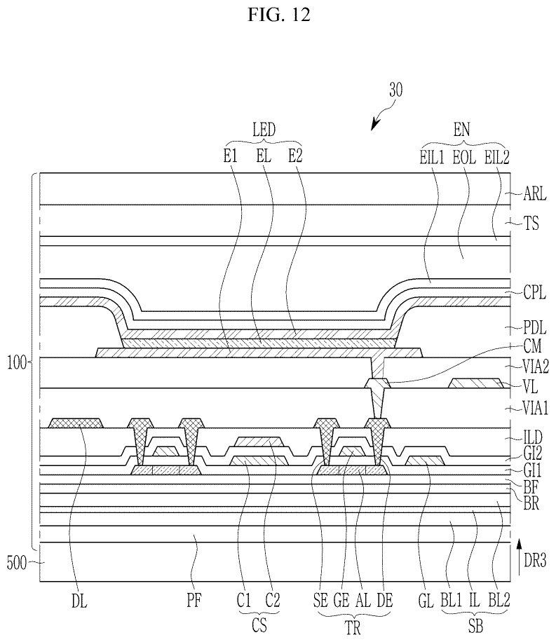

FIG. 12 is a schematic cross-sectional view of a display device according to an embodiment.

Referring to FIG. 12, the shown cross-section may correspond to approximately one pixel area. A display device 30 may include a display panel 100 and a cover film 500 printed or coated on a back surface of the display panel 100.

The display panel 100 basically includes a substrate SB, a transistor TR disposed on the substrate SB, and a light-emitting diode LED connected to the transistor TR. The light-emitting diode LED may correspond to a pixel.

The substrate SB may be a flexible substrate SB capable of bending, folding, rolling, and/or the like. The substrate SB may be a multilayer including a first base layer BL1, an inorganic layer IL, and a second base layer BL2. The first base layer BL1 and the second base layer BL2 may contain polymer resin such as polyimide, polyamide, or polyethylene terephthalate. The first base layer BL1 and the second base layer BL2 may be polymer layers. A barrier layer BR that prevents moisture, oxygen, and/or the like from penetrating may be disposed on the substrate SB. The barrier layer BR may include an inorganic insulating material such as silicon nitride (SiNₓ), silicon oxide (SiOₓ), silicon oxynitride (SiOₓN_{y}), and/or the like, and may be a single layer or multilayer.

A buffer layer BF may be disposed on the barrier layer BR. The buffer layer BF may improve characteristics of a semiconductor layer by blocking impurity from the substrate SB during the formation of the semiconductor layer, and may relieve the stress of the semiconductor layer by planarizing a surface of the substrate SB. The buffer layer BF may include an inorganic insulating material such as silicon nitride, silicon oxide, silicon oxynitride, and the like, and may be a single layer or multilayer. The buffer layer BF may include amorphous silicon (a-Si).

A semiconductor layer AL of the transistor TR may be disposed on the buffer layer BF. The semiconductor layer AL may include a first region, a second region, and a channel region between the first region and the second region. The semiconductor layer AL may include any one of amorphous silicon, polycrystalline silicon, and oxide semiconductor. The oxide semiconductor may include at least one of zinc (Zn), indium (In), gallium (Ga), and tin (Sn). For example, the semiconductor layer AL may include low temperature polycrystalline silicon (“LTPS”) or indium-gallium-zinc oxide (“IGZO”).

A first gate insulating layer GI1 may be disposed on the semiconductor layer AL. The first gate insulating layer GI1 may include an inorganic insulating material such as silicon nitride, silicon oxide, silicon oxynitride, and the like, and may be a single layer or multilayer.

A first gate conductive layer that may include a gate electrode GE of the transistor TR, a gate line GL, and a first electrode C1 of the storage capacitor CS may be disposed on the first gate insulating layer GI1. The first gate conductive layer may include molybdenum (Mo), aluminum (AI), copper (Cu), titanium (Ti), and/or the like, and may be a single layer or multilayer.

A second gate insulating layer GI2 may be disposed on the first gate conductive layer. The second gate insulating layer GI2 may include an inorganic insulating material such as silicon nitride, silicon oxide, silicon oxynitride, and the like, and may be a single layer or multilayer.

A second gate conductive layer that may include a second electrode C2 of the storage capacitor CS may be disposed on the second gate insulating layer GI2. The second gate conductive layer may include molybdenum (Mo), aluminum (AI), copper (Cu), titanium (Ti), and/or the like, and may be a single layer or multilayer.

An interlayer-insulating layer ILD may be disposed on the second gate insulating layer GI2 and the second gate conductive layer. The interlayer-insulating layer ILD may include an inorganic insulating material such as silicon nitride, silicon oxide, silicon oxynitride, and the like, and may be a single layer or multilayer.

A first data conductive layer that may include a first electrode SE and a second electrode DE of the transistor TR, and a data line DL may be disposed on the interlayer-insulating layer ILD. The first electrode SE and the second electrode DE may be connected to a first region and a second region of the semiconductor layer AL, respectively, through contact holes defined in the insulation layers GI1, GI2, and ILD. One of the first electrode SE and the second electrode DE may be a source electrode, and the other may be a drain electrode. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and/or the like, and may be a single layer or multilayer.

A first planarization layer VIA1 may be disposed on the first data conductive layer. The first planarization layer VIA1 may include an organic insulating material such as a common polymer such as polymethylmethacrylate and polystyrene, polymer derivatives having phenolic groups, an acryl-based polymer, an imide polymer (e.g., polyimide), and a siloxane polymer.

A second data conductive layer that may include a power line VL, a connecting member CM, and/or the like may be disposed on the first planarization layer VIA1. The power line VL may transmit a voltage such as a driving voltage, a common voltage, an initialization voltage, a reference voltage, and the like. The connecting member CM may be connected to the second electrode DE of the transistor TR through a contact hole defined in the first planarization layer VIA1. The second data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and/or the like, and may be a single layer or multilayer.

A second planarization layer VIA2 may be disposed on the second data conductive layer. The second planarization layer VIA2 may include an organic insulating material such as a common polymer such as polymethylmethacrylate and polystyrene, polymer derivatives having phenolic groups, an acryl-based polymer, an imide polymer (e.g., polyimide), and a siloxane polymer.

A first electrode E1 of the light-emitting diode LED may be disposed on the second planarization layer VIA2. The first electrode E1 may be called a pixel electrode. The first electrode E1 may be connected to the connecting member CM through a contact hole defined in the second planarization layer VIA2. Therefore, the first electrode E1 is electrically connected to the second electrode DE of the transistor TR and may receive a driving current that controls the luminance of the light-emitting diode. The transistor TR to which the first electrode E1 is connected may be a driving transistor or a transistor electrically connected to the driving transistor. The first electrode E1 may be formed of a reflective conducting material or a semi-permeable conducting material, or may be formed of a transparent conductive material. The first electrode E1 may include a transparent conductive material such as indium tin oxide (“ITO”), indium zinc oxide (“IZO”), and the like. The first electrode E1 may include lithium (Li), calcium (Ca), aluminum (AI), silver (Ag), magnesium (Mg), gold (Au), and/or the like.

A pixel definition layer PDL may be disposed on the second planarization layer VIA2 and the first electrode E1. The pixel definition layer PDL may be called a bank or partitioning wall and may define an opening that overlaps the first electrode E1 in a plan view. The pixel definition layer PDL may include an organic insulating material such as a common polymer such as polymethylmethacrylate and polystyrene, polymer derivatives having phenolic groups, an acryl-based polymer, an imide polymer (e.g., polyimide), and a siloxane polymer.

A light-emitting layer EL of the light-emitting diode LED may be disposed on the first electrode E1. In addition to the light-emitting layer EL, a function layer including at least one of a hole injection layer (“HIL”), a hole transport layer (“HTL”), an electron transport layer (“ETL”), and an electron injection layer (“EIL”) may be disposed on the first electrode E1.

The second electrode E2 of the light-emitting diode LED may be disposed on the light-emitting layer EL. The second electrode E2 may be called a common electrode. The second electrode E2 may be formed to have light transmittance by forming a thin layer with a metal or metal alloy with low work function, such as calcium (Ca), barium (Ba), magnesium (Mg), aluminum (AI), or silver (Ag). The second electrode E2 may include a transparent conductive oxide such as indium tin oxide (ITO) or indium zinc oxide (IZO).

The first electrode E1, light-emitting layer EL, and second electrode E2 of each pixel may form a light-emitting diode LED such as an organic light-emitting diode. The first electrode E1 may be an anode, and the second electrode E2 may be a cathode. The light-emitting region of a light-emitting diode LED may correspond to a pixel.

A capping layer CPL may be disposed on the second electrode E2. The capping layer CPL may improve optical efficiency by adjusting the refractive index. The capping layer CPL may be disposed to wholly cover the second electrode E2. The capping layer CPL may include an organic insulating material, or may include an inorganic insulating material.

An encapsulation layer EN may be disposed on the capping layer CPL. The encapsulation layer EN may encapsulate the light-emitting diode LED to prevent moisture or oxygen from penetrating from the outside. The encapsulation layer EN may be a thin film encapsulation layer in which an organic layer EOL is disposed between the first inorganic layer EIL1 and the second inorganic layer EIL2.

A touch sensor layer TS including touch electrodes may be disposed on the encapsulation layer EN. An anti-reflection layer ARL may be disposed on the touch sensor layer TS to reduce external light reflection.

A protective film PF may be disposed below the substrate SB. The protective film PF may protect the display panel 100 during a manufacturing process of the display device. The protective film PF may contain a polymer such as polyethylene terephthalate, a silicon-based polymer (e.g., polydimethylsiloxane), an elastomer (e.g., elastomeric polyurethane).

The cover film 500 may be disposed below the protective film PF. The cover film 500 may have, for example, the structures described above with reference to FIG. 4 to FIG. 10. Unlike what is shown, the display panel 100 may not include the protective film PF, and the cover film 500 may be printed or coated on the back surface of the substrate SB.

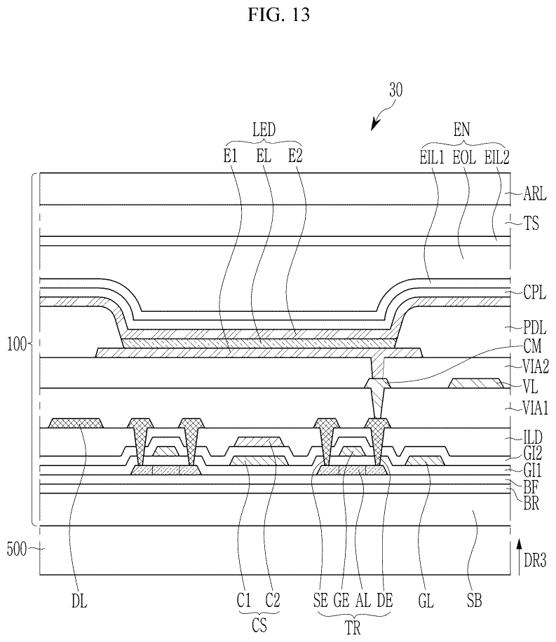

FIG. 13 is a schematic cross-sectional view of a display device according to an embodiment.

A display device 30 shown in FIG. 13 is different from the display device 30 shown in FIG. 12 in a substrate SB of a display panel 100. The substrate SB may be a rigid substrate made of a material such as glass. The display panel 100 may not include a protective film that may be disposed on a back surface of the substrate SB. The cover film 500 may be printed or coated on the back surface of substrate SB. Unlike what it is shown, the display panel 100 may include a protective film disposed on the back surface of the substrate SB, and a cover film 500 may be printed or coated on the back surface of the protective film.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A display device comprising:
a display panel;
a flexible printed circuit board connected to the display panel; and
a cover film printed or coated on a back surface of the display panel,
wherein the cover film defines a groove pattern therein, which accommodates at least a part of the flexible printed circuit board.

2. The display device of claim 1, wherein
the at least a part of the groove pattern has a planar shape, which corresponds to a planar shape of at least a part of the flexible printed circuit board.

3. The display device of claim 1, wherein
the groove pattern comprises a first groove having a first depth from a surface of the cover film and a second groove having a second depth from the surface of the cover film, and the second depth is greater than the first depth.

4. The display device of claim 3, wherein
the flexible printed circuit board comprises a body on which an electronic component is disposed, a tail extending from the body, and a connector disposed at an end of the tail, and
the tail is disposed in the first groove and the connector is disposed in the second groove.

5. The display device of claim 1, wherein
the cover film further has an additional groove pattern, which is spaced apart from the groove pattern.

6. The display device of claim 1, wherein
the cover film further has a protrusion pattern protruded from a major back surface of the cover film.

7. The display device of claim 1, wherein
the cover film further has a bump protruding from a major back surface of the cover film at an edge of the cover film.

8. The display device of claim 1, wherein:
the display panel comprises a substrate, a transistor disposed on the substrate, a light-emitting device electrically connected to the transistor, and a protective film disposed on a back surface of the substrate, and
the cover film directly contacts the protective film.

9. The display device of claim 8, wherein:
the substrate is a flexible substrate including a polymer layer.

10. The display device of claim 1, wherein
the display panel comprises a substrate, a transistor disposed on the substrate, and a light-emitting device electrically connected to the transistor, and
the cover film directly contacts the substrate.

11. The display device of claim 10, wherein
the substrate is a rigid substrate including glass.

12. The display device of claim 1, wherein:
the cover film is configured to provide at least one of functions of shielding, buffering, light blocking, and heat dissipation.

13. The display device of claim 12, wherein
the cover film is configured to provide different functions depending on regions of the cover film.

14. An electronic device comprising a housing and a display device disposed in the housing, wherein
the display device comprises:
a display panel; and
a cover film printed or coated on a back surface of the display panel, and
wherein the cover film defines a groove pattern therein, which accommodates at least a part of a component.

15. The electronic device of claim 14, wherein
the display device further comprises a flexible printed circuit board connected to the display panel, and
at least a part of the groove pattern has a planar shape corresponding to a planar shape of at least a part of the flexible printed circuit board.

16. The electronic device of claim 15, wherein
the groove pattern comprises a first groove having a first depth from a surface of the cover film and a second groove having a second depth from the surface of the cover film, and the second depth is greater than the first depth.

17. The electronic device of claim 16, wherein
the flexible printed circuit board comprises a body on which an electronic component is disposed, a tail extending from the body, and a connector disposed at an end of the tail, and
the tail is disposed in the first groove and the connector is disposed in the second groove.

18. The electronic device of claim 14, wherein
the cover film further has a protrusion pattern protruded from a major back surface of the cover film.

19. The electronic device of claim 14, wherein
the display panel comprises a substrate, a transistor disposed on the substrate, a light-emitting device electrically connected to the transistor, and a protective film disposed on a back surface of the substrate, and
the cover film directly contacts the protective film.

20. The electronic device of claim 14, wherein
the display panel comprises a substrate, a transistor disposed on the substrate, and a light-emitting device electrically connected to the transistor, and
the cover film directly contacts the substrate.
